(19) United States
(12) Patent Application Publication
(10) Pub. No.: US 2024/0004776 A1
(43) Pub. Date: Jan. 4, 2024

(54) USER-SPACE EMULATION FRAMEWORK FOR HETEROGENEOUS SOC DESIGN

(71) Applicants: Arizona Board of Regents on Behalf of Arizona State University, Scottsdale, AZ (US); Arizona Board of Regents on Behalf of the University of Arizona, Tucson, AZ (US); Board of Regents, The University of Texas System, Austin, TX (US); Carnegie Mellon University, Pittsburgh, PA (US)

(72) Inventors: Umit Ogras, Tempe, AZ (US); Radu Marculescu, Austin, TX (US); Ali Akoglu, Tucson, AZ (US); Chaitali Chakrabarti, Tempe, AZ (US); Daniel Bliss, Phoenix, AZ (US); Samet Egemen Arda, Chandler, AZ (US); Anderson Sartor, La Jolla, CA (US); Nirmal Kumbhare, Tucson, AZ (US); Anish Krishnakumar, Madison, WI (US); Joshua Mack, Tucson, AZ (US); Ahmet Goksoy, Madison, WI (US); Sumit Mandal, Madison, WI (US)

(21) Appl. No.: 18/249,885

(22) PCT Filed: Oct. 22, 2021
(86) PCT No.: PCT/US2021/056290

§ 371 Date: Apr. 20, 2023

Related U.S. Application Data
(60) Provisional application No. 63/104,272, filed on Oct. 22, 2020.

(51) Int. Cl. G06F 11/34; G06F 9/50; G06N 7/01

(52) U.S. Cl. CPC G06F 11/3457; G06N 7/01; G06F 9/5038; G06F 11/3414

(57) ABSTRACT

A user-space emulation framework for heterogeneous system-on-chip (SoC) design is provided. Embodiments described herein propose a portable, Linux-based emulation framework to provide an ecosystem for hardware-software co-design of heterogenous SoCs (e.g., domain-specific SoCs (DSSoCs)) and enable their rapid evaluation during the pre-silicon design phase. This framework holistically targets three key challenges of heterogeneous SoC design: accelerator integration, resource management, and application development. These challenges are addressed via a flexible and lightweight user-space runtime environment that enables easy integration of new accelerators, scheduling heuristics, and user applications, and the utility of each is illustrated through various case studies. A prototype compilation toolchain is introduced that enables automatic mapping of unlabeled C code to heterogeneous SoC platforms. Taken together, this environment offers a unique ecosystem to rapidly perform functional verification and obtain performance and utilization estimates that help accelerate convergence towards a final heterogeneous SoC design.

### RELATED APPLICATIONS

This application claims the benefit of provisional patent application Ser. No. 63/104,272, filed Oct. 22, 2020, the disclosure of which is hereby incorporated herein by reference in its entirety.

### GOVERNMENT SUPPORT

This invention was made with government support under FA8650-18-2-7860 awarded by the Defense Advanced Research Projects Agency. The government has certain rights in the invention.

### FIELD OF THE DISCLOSURE

The present disclosure is related to hardware-software co-design.

### BACKGROUND

As technology scaling becomes a challenge, System-on-Chip (SoC) architects are exploring the capabilities of Domain-Specific SoCs (DSSoCs) to effectively balance performance and flexibility. DSSoC architectures are characterized by a heterogeneous collection of general-purpose cores and programmable accelerators tailored to a particular application domain. The uniqueness of DSSoC architectures gives rise to a number of challenges.

First, the design and implementation of hardware accelerators is time-consuming and complex. DSSoCs are characterized by application domains with recurring compute and/or energy-intensive routines, and an effective DSSoC will require a collection of accelerators built specifically to handle these. Hardware implementation and functional verification of custom accelerators while meeting area, timing, and power constraints at the system-level remains a significant challenge.

Second, DSSoCs commonly operate in real-time environments where time-constrained applications arrive dynamically. For a fixed collection of heterogeneous accelerators, this requires dynamic and low-overhead scheduling strategies to enable effective runtime management and task partitioning across these accelerators. A common approach in enabling rich scheduling algorithms that maximize processing element (PE) utilization is to model applications as directed acyclic graphs (DAGs). Assuming DAG-based applications, the complexity of managing a large collection of task-dependencies and prioritizing execution across a variety of custom and general-purpose PEs makes scheduling a non-trivial problem in DSSoCs.

Third, like any heterogeneous platform, it is crucial to provide productive toolchains by which application developers can port their applications to DSSoCs. In particular, target applications must be analyzed in terms of their phases of execution, and the portions of each application that are amenable to heterogeneous execution must be mapped as such to the various resources present on a given DSSoC. Providing application developers a rich environment by which they can explore different application partitioning strategies contextualized by realistic scheduler models and accelerator interfaces is critical in enabling efficient execution on production hardware.

Finally, in a production DSSoC, effective on-chip communication is crucial to exploit maximum performance with minimum latency and energy consumption. Hence, there is a need for efficient Network-on-Chip (NoC) fabric that is tailored for a given DSSoC's collection of accelerators. Together with the aforementioned challenges, it is a complex task to design and evaluate DSSoC architectures.

### SUMMARY

A user-space emulation framework for heterogeneous system-on-chip (SoC) design is provided. Embodiments described herein propose a portable, Linux-based emulation framework to provide an ecosystem for hardware-software co-design of heterogeneous SoCs (e.g., domain-specific SoCs (DSSoCs)) and enable their rapid evaluation during the pre-silicon design phase. This framework holistically targets three key challenges of heterogeneous SoC design: accelerator integration, resource management, and application development. These challenges are addressed via a flexible and lightweight user-space runtime environment that enables easy integration of new accelerators, scheduling heuristics, and user applications, and the utility of each is illustrated through various case studies.

With signal processing (WiFi and RADAR) as the target domain, this framework is used to evaluate the performance of various dynamic workloads on hypothetical heterogeneous SoC hardware configurations composed of mixtures of central processing unit (CPU) cores and Fast Fourier Transform (FFT) accelerators using a Zynq UltraScale+™ MPSoC. The portability of this framework is shown by conducting a similar study on an Odroid platform composed of big.LITTLE ARM clusters. Finally, a prototype compilation toolchain is introduced that enables automatic mapping of unlabeled C code to heterogeneous SoC platforms. Taken together, this environment offers a unique ecosystem to rapidly perform functional verification and obtain performance and utilization estimates that help accelerate convergence towards a final heterogeneous SoC design.

An exemplary embodiment provides an emulation environment for heterogeneous SoC design. The emulation environment includes a workload manager configured to schedule application tasks onto heterogeneous processing elements (PEs) in a heterogeneous SoC based on a scheduling policy and a resource manager configured to simulate a test hardware configuration using the heterogeneous PEs and execute the application tasks scheduled by the workload manager.

Another exemplary embodiment provides a method for developing an application for heterogeneous SoC implementation. The method includes obtaining an application code, converting the application code into a platform-independent hardware representation, and generating an object notation-based representation of the application code for heterogeneous SoC implementation from the platform-independent hardware representation.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a block schematic diagram of an exemplary emulation framework according to embodiments described herein.

FIG. 2 is a block schematic diagram of an exemplary application handler in the emulation framework of FIG. 1.

FIG. 3 is an object notation representation of an exemplary range detection task flow in the application handler of FIG. 2.

FIG. 4 is a flowchart illustrating an exemplary execution of a workload manager in the emulation framework of FIG. 1.

FIG. 5 is a flowchart illustrating an exemplary execution of a resource manager thread.

FIG. 6 is a block schematic diagram of an exemplary dynamic tracing-based software flow used to automatically convert unlabeled C applications to directed acyclic graph (DAG)-based applications.

FIG. 7 is a schematic block diagram illustrating data transfer mechanisms among the host software application, memory and accelerators.

FIG. 8 is a block schematic diagram of WiFi transmitter and receiver applications used to evaluate embodiments of the emulation framework.

FIG. 9 is a block schematic diagram of an exemplary pulse Doppler application used to evaluate embodiments of the emulation framework.

FIG. 10A is a graphical representation of execution time across various heterogeneous system-on-chip (SoC) configurations for a workload composed of single instances of Pulse-Doppler, range detection, and WiFi applications.

FIG. 10B is a graphical representation of average processing element (PE) utilization across various heterogeneous SoC configurations for a workload composed of single instances of Pulse-Doppler, range detection, and WiFi applications.

FIG. 11A is a graphical representation of workload execution time for different scheduling policies on an exemplary heterogeneous SoC.

FIG. 11B is a graphical representation of average scheduling overhead for different scheduling policies on an exemplary heterogeneous SoC.

FIG. 12 is a graphical representation of an execution time trend with respect to change in job injection rate for different combinations of BIG and LITTLE cores on an exemplary heterogeneous SoC.

FIG. 13 is a block diagram of a computer system suitable for implementing an emulation framework for heterogeneous SoC design according to embodiments disclosed herein.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

A user-space emulation framework for heterogeneous system-on-chip (SoC) design is provided. Embodiments described herein propose a portable, Linux-based emulation framework to provide an ecosystem for hardware-software co-design of heterogeneous SoCs (e.g., domain-specific SoCs (DSSoCs)) and enable their rapid evaluation during the pre-silicon design phase. This framework holistically targets three key challenges of heterogeneous SoC design: accelerator integration, resource management, and application development. These challenges are addressed via a flexible and lightweight user-space runtime environment that enables easy integration of new accelerators, scheduling heuristics, and user applications, and the utility of each is illustrated through various case studies.

With signal processing (WiFi and RADAR) as the target domain, this framework is used to evaluate the performance of various dynamic workloads on hypothetical heterogeneous SoC hardware configurations composed of mixtures of central processing unit (CPU) cores and Fast Fourier Transform (FFT) accelerators using a Zynq UltraScale+™ MPSoC. The portability of this framework is shown by conducting a similar study on an Odroid platform composed of big.LITTLE ARM clusters. Finally, a prototype compilation toolchain is introduced that enables automatic mapping of unlabeled C code to heterogeneous SoC platforms. Taken together, this environment offers a unique ecosystem to rapidly perform functional verification and obtain performance and utilization estimates that help accelerate convergence towards a final heterogeneous SoC design.

### I. Introduction

The present disclosure proposes an open-source, portable user-space emulation framework that seeks to address the first three challenges of accelerator design, resource management, and application development in the early, pre-silicon stages of heterogeneous SoC (e.g., DSSoC) development. This framework is a lightweight Linux application that is designed to be suitable for emulating heterogeneous SoCs on various commercial off-the-shelf (COTS) computing systems. For the above three challenges, it provides distinct plug-and-play integration points where developers can individually integrate and evaluate their applications, schedulers, and accelerator IPs in a realistic and holistic system before a full virtual platform or platform silicon is made available.

Notably, to enable rapid application integration, the framework also includes a prototype compilation toolchain that allows users to map monolithic, unlabeled C applications to directed acyclic graph (DAG)-based applications as an alternative to requiring hand crafted, custom integration for each application in a domain. On top of enabling functional verification for each of these aspects of a heterogeneous SoC separately, this unified environment assists in deriving relative performance estimates among different combinations of applications, scheduling algorithms, and heterogeneous SoC hardware configurations. These estimates are expected to assist SoC developers narrow their configuration space prior to performing in depth, cycle-accurate simulations of a complete system and accelerate convergence to a final heterogeneous SoC design.

Section II introduces the proposed framework and describes the functionality of its key components. The interfaces required to integrate new schedulers, applications and processing elements (PEs) are also described. Section III presents various use-cases of the emulation framework based on real applications from the signal processing domain on COTS platforms. Section IV presents a computer system used for implementing embodiments described herein.

### II. Emulation Framework

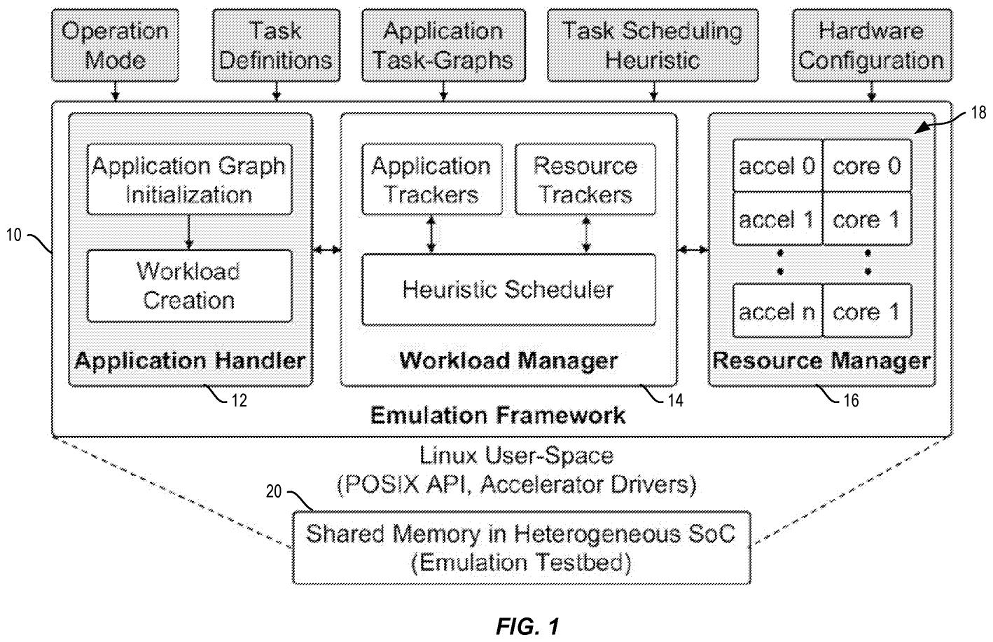

FIG. 1 is a block schematic diagram of an exemplary emulation framework 10 according to embodiments described herein. It is composed of three key components: an application handler 12, a workload manager 14, and a resource manager 16. The application handler 12 is responsible for initializing the framework-compatible representations of all the application task-graphs and create a workload for the emulation framework 10 (also referred to as a framework environment). The workload manager 14 schedules tasks from the DAGs onto the PEs 18 based on the scheduling policy chosen by the user. The resource manager 16 is used to create the test hardware configuration using the PEs 18 in the SoC and coordinate the execution of the tasks with the workload manager 14. The emulation framework 10 uses one of the CPU cores among the available pool of PEs 18 to act as a management processor. This core is dedicated to run the application handler 12 and the workload manager 14 modules. The rest of the PEs 18 form the resource pool from which resource manager 16 can instantiate different test hardware configurations. All the components of the emulation framework 10 and the tasks for each application are written using C/C++. The emulation framework 10 operates in the Linux user-space and requires POSIX thread library. This makes it portable across wide range of commercial SoC platforms. By default, the emulation framework 10 is integrated with the applications from the signal processing domain, such as Radar and WiFi, to aid the development of heterogeneous SoCs (e.g., DSSoCs) for software defined radios (SDR).

At the start of an emulation, the emulation framework 10 performs an initialization phase in which the application handler 12 initializes a queue containing the required workload, and allocates the memory required by the emulation workload in the main memory. In the same phase, the resource manager 16 initializes the target heterogeneous SoC configuration by using the real PEs 18 in the underlying SoC. Post the initialization phase, the workload manager 14 drives the emulation by dynamically injecting the applications from the workload queue and coordinating with the resource manager 16 to schedule tasks on the idle PEs 18. Before termination, the emulation framework 10 collects the scheduling statistics for all the applications and their tasks. These statistics can later be used to evaluate the performance of the emulated heterogeneous SoC. The communication between different PEs 18 is performed using the shared memory 20 of the platform. As a result, while this framework can assist in hardware, scheduler, and application design, it currently is limited in its ability to handle hypothetical Network-on-Chip (NoC) architectures. The subsequent subsections present details of all the components in the emulation framework 10 and detail the steps that must be taken to integrate new features.

A. Application Handler

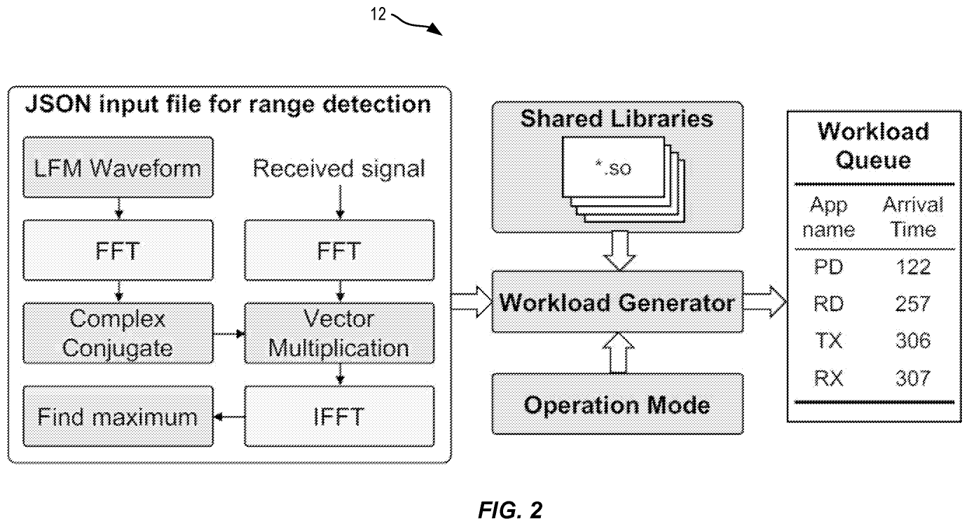

FIG. 2 is a block schematic diagram of an exemplary application handler 12 in the emulation framework 10 of FIG. 1. In the emulation framework 10, the application handler 12 is responsible for parsing and initializing the applications from their respective task-graph representations. FIG. 2 presents the functionality of the application handler 12. Each user application in the emulation framework 10 consists of two components: a shared object file that contains the functions (kernels) that a user's application requires, and a JavaScript object notation (JSON)-based DAG that describes their dependency relationships. These JSON-based DAGs describe the kernels in a given application along with their interconnections, communication costs (data transfer volumes), execution time cost on supported platforms (CPU, accelerator), and the names of the function symbols associated with each kernel in the user's shared object application. An illustrative example uses radar-based range detection as an application in the domain of software-defined radio. The task flow graph for range detection is shown as an input to the workload generator in FIG. 2.

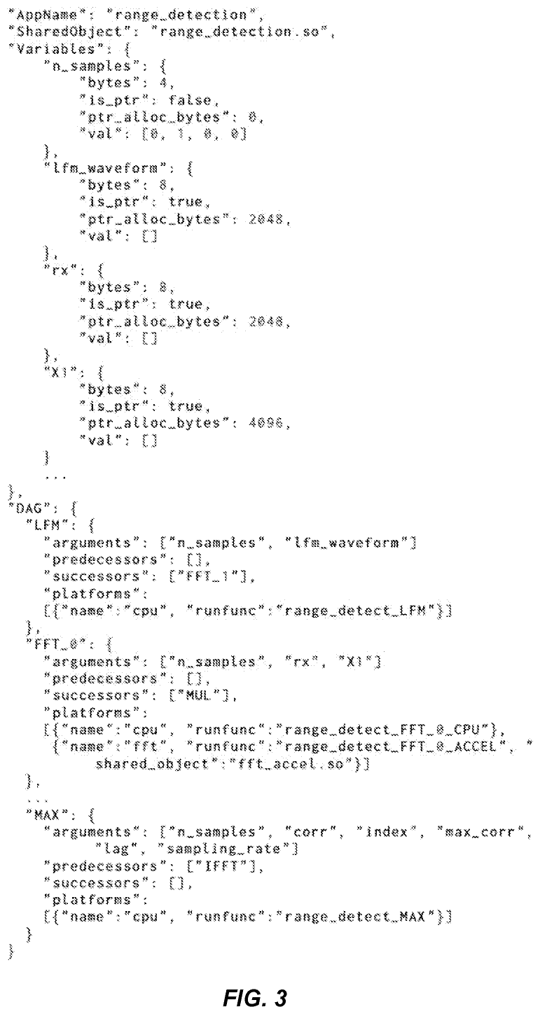

FIG. 3 is an object notation representation of an exemplary range detection task flow in the application handler 12 of FIG. 2. In an exemplary aspect, FIG. 3 illustrates a range detection JSON in which the AppName, SharedObject, and Variables keys give global information about the application: namely its name within the emulation framework 10, the shared object that contains the implementation for each function referenced, and the list of all program variables that will be required by nodes within this application. The Variables key, in particular, has a value that is heavily application dependent and defines the storage requirements and initialization values for any variable in the program. Each variable is named by its key, and the values inside—bytes, is_ptr, ptr_alloc_bytes, and val—refer respectively to the number of bytes it requires to represent its type, whether this type is itself a pointer, the amount of storage that pointer requires, and a list of initial bytes with which to populate this variable. As an example, the variable n_samples was originally a 32-bit integer data type with a value of 256. As such, it is given 4 bytes of storage space, and it is initialized with a little-endian representation of 256 as the byte vector [0,1,0,0]. As another example, lfm_waveform was originally a floating-point array for 512 32-bit floats, or 2048 bytes. Therefore, this value is given 8 bytes (as pointer types are 8-bytes on 64-bit systems), it is flagged as a pointer type, and this variable itself is assigned a location in the heap that is allocated for 2048 bytes upon initialization by the emulation framework 10.

The DAG key in FIG. 3 gives structure of the application graph itself, with each key corresponding to a node in the application graph containing information about its predecessors, successors, and supported execution platforms. On application startup, the runtime finds the shared object file referenced in the application's JSON and begins parsing the graph. As graph parsing proceeds, it looks up every runfunc it finds in the corresponding shared object and associates it with each given DAG node. Optionally, each “platform” in a node can include a custom shared object that is referenced specifically to look up that function, such as an FFT invocation that references an “fft_accel.so” shared object as shown in the “FFT_0” node. With all applications parsed, the application handler 12 performs initialization of each instance of the requested applications by initializing all of an application's variables as specified in the JSON. After this, it proceeds to generate the requested workload. The workload can be generated to run in either validation or performance mode. Validation mode involves generating all application instances and injecting them at t=0, with the emulation finishing once all applications are complete. Performance mode involves generating a probabilistic trace, where applications are given injection times t∈[0, t_{end}) and injected throughout the emulation, with the process finishing once a defined time limit t_{end} is reached. In the performance mode, a user needs to provide the time period for the injection along with the probability of injection.

As an example, a user may wish to execute three instances of range detection in validation mode. Given this request, the emulation framework 10 will parse all available applications, and it will output an error if, at the end of this process, it has not detected range detection as referenced by its AppName. Assuming the emulation framework 10 was able to find and parse the archetypal instance of range detection, it will then instantiate three copies of this base application. Each application instance will have all its variables allocated and initialized as described in the JSON. After initialization, the application will be enqueued into a workload queue and passed to the workload manager 14 to emulate application arrival and scheduling.

To integrate new applications, a developer has three choices. First, they can build a DAG-based application entirely from scratch, compile it into a shared object of kernels, and link them together with a hand-crafted JSON-based DAG representation. Second, they can choose to leverage the existing library of kernels present in other applications and define a new application simply by linking them together in a novel way. In this way, many application domains can be rapidly implemented through piecemeal combinations of common kernels solely through defining how they become linked together. Third, a developer can utilize an automated workflow provided as a part of the emulation framework 10 that allows for automatic, if less optimized, conversion from monolithic C code into DAG-based applications. Further details about the functionality and capabilities of this third option are presented in Section II-D.

B. Workload Manager

The workload manager 14 drives the emulation in the emulation framework 10. It is responsible for tracking the emulation time, injecting applications, implementing scheduling policies, and coordinating with the resource managers 16 to execute the tasks on the PEs 18. The workload manager 14 uses the workload queue from the application handler 12 and the task scheduling algorithm from the user as its inputs. At run-time, the user is given the option to select either one of the available scheduling policies from the library or use the custom scheduling algorithm. The default scheduling library is composed of minimum execution time (MET), first ready-first start (FRFS), earliest finish time (EFT), and random (RANDOM).

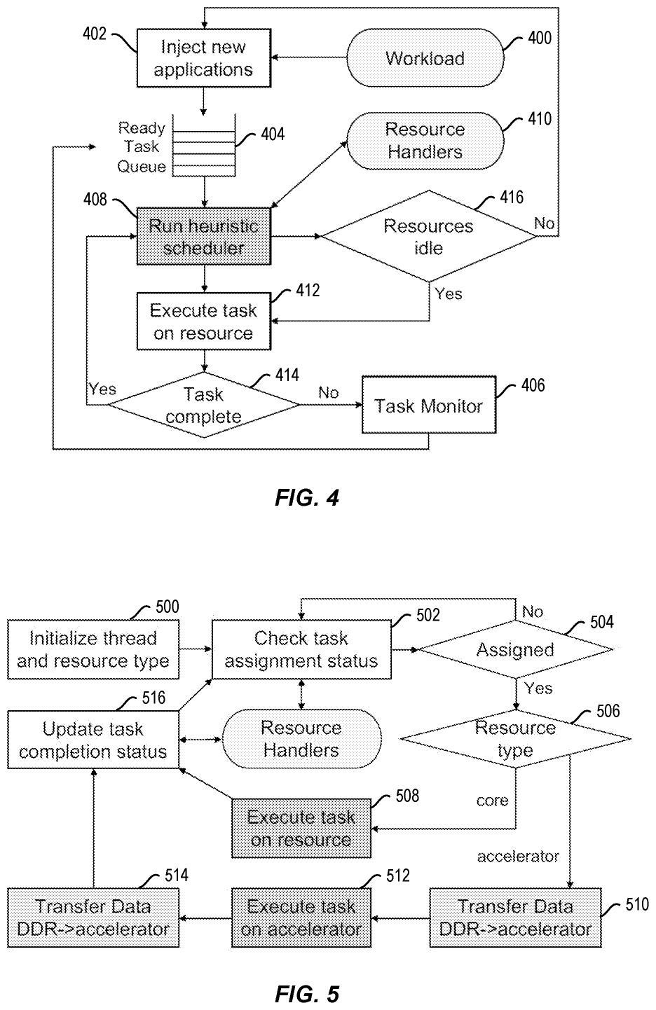

FIG. 4 is a flowchart illustrating an exemplary execution of the workload manager 14 in the emulation framework 10 of FIG. 1. It begins by capturing the system clock as the reference start time for the emulation. All the arrival timestamps in the workload queue are relative to this reference start time. In this disclosure, emulation time is defined as the time spent in execution after capturing the reference start time. The workload manager 14 regularly compares the arrival time of an instance at the head of the workload queue with the current emulation time. If the current emulation time exceeds the instance arrival time, then it dequeues the head entry (application instance) from the workload queue (block 400) and injects the instance into ongoing emulation (block 402). The workload manager 14 appends the head nodes of the newly injected application DAGs into the ready task list (block 404). The ready task list tracks the tasks that are ready to be executed on the emulated SoC resources. After injecting new applications, the workload manager 14 monitors the completion status of the running tasks via resource handler objects. A resource handler object is used to manage the communication and synchronization between the workload manager 14 and the resource manager 16 threads. Each PE 18 in the emulated SoC is assigned a dedicated resource handler object. After monitoring PEs 18, the workload manager 14 updates the ready task list with the outstanding (unexecuted) tasks (block 406). An outstanding task is appended in the ready task list if all of its predecessor tasks are completed. Next, the user-selected scheduling policy is applied on the ready task list and the tasks selected for scheduling are removed from the list (block 408). These tasks are communicated to the resource managers 16 of their assigned PEs 18 via resource handlers (block 410).

To utilize a user-defined scheduling policy, an additional policy needs to be defined in scheduler.cpp and a dispatch call needs to be added in the same file's performScheduling function. This new policy must accept parameters such as the ready queue of tasks and handles for each of the “resource handler” objects. Each task consists of a DAG node data structure with all the information necessary for scheduling, dispatch, and measurement of a single node's performance throughout the emulation framework 10. Each resource handler object is associated with a unique PE 18. It is composed of fields that track PE 18 availability, type, and ID along with its workload and synchronization lock. The PE availability field is used to communicate resource state between the workload manager 14 and resource manager 16. A PE's availability status can be idle, run, or complete. A thread monitoring or modifying the status field should acquire the PE's synchronization lock, read or write to the status field, and release the lock. Integrating a new scheduling algorithm should begin by checking the availability for all the PEs 18 by querying whether their status field indicates they are idle. Next, the algorithm performs the task-to-PE mapping on the ready tasks and transfers them over to the resource manager 16 of their mapped PEs 18 via resource handlers. Then, the algorithm commands the resource manager 16 to start executing the task by modifying the PE state to run (block 412). The resource manager 16 notifies the task completion to the workload manager 14 by modifying the status to complete (block 414). Post notification, the workload manager 14 appends the outstanding tasks in the ready list and updates PE status to idle (block 416).

C. Resource Manager

At the start of emulation, the emulation framework 10 reads the number and types of PEs 18 from the input configuration file and initializes the dedicated threads of the resource manager 16 for each PE 18. These threads are responsible for controlling the operations on their assigned PEs 18. These operations involve the execution of the assigned task, manage the data transfer in between the main memory and the custom accelerator (if required), and coordinate the PE availability status with the workload manager 14. If the input PE type is CPU, then the emulation framework 10 assigns the affinity of its resource manager 16 thread to one of the unused CPU cores in the underlying SoC. For all other PE types, their resource manager 16 thread assignment begins with the unused CPU cores and then they are evenly distributed among all the CPU cores in the resource pool. To derive relative performance estimates, it is recommended to instantiate a test configuration such that all of the resource manager 16 threads are assigned to a separate CPU core to reduce the impact of context switching among the threads.

FIG. 5 is a flowchart illustrating an exemplary execution of a resource manager 16 thread. It uses the resource handler object to communicate and synchronize with the workload manager 14. After initialization (block 500), it checks the task assignment status for the resource in its resource handler (block 502). If a task is assigned (block 504), depending on its resource types (core or accelerator) (block 506), it follows the execution step as shown in the FIG. 5. If the resource type is core, it executes the executable of the task without any explicit data transfer (block 508). However, if the resource type is an accelerator, then the resource manager 16 thread transfers the data from the framework memory space (DDR) to the local memory of the accelerator (Block RAM in case of FPGAs) (block 510), and it follows by commanding accelerator to process the data (block 512). It monitors the state of the accelerator either using polling or interrupts, and then it transfers data back from the accelerator to the memory space of the emulation framework 10 (block 514). The emulation framework 10 migrates each accelerator manager thread into sleep state during the processing of the data on the accelerator. This allows other manager threads to initiate data transfer and monitor status of their corresponding accelerators if multiple resource managers 16 share the CPU core. To integrate new accelerators, a user is expected to implement the blocks required to transfer data between CPU and accelerator, and the programming logic to begin and monitor the completion status of the accelerators (block 516). In the released repository, DMA interface is implemented between accelerators and CPU on ZCU102 platform.

D. Automatic Application Conversion

As an alternative to requiring hand-crafted DAG-based applications, a basic toolchain is also provided that allows for automatic conversion of monolithic, unlabeled C applications to DAG-based applications through a combination of dynamic tracing-based kernel/node detection and LLVM code outlining.

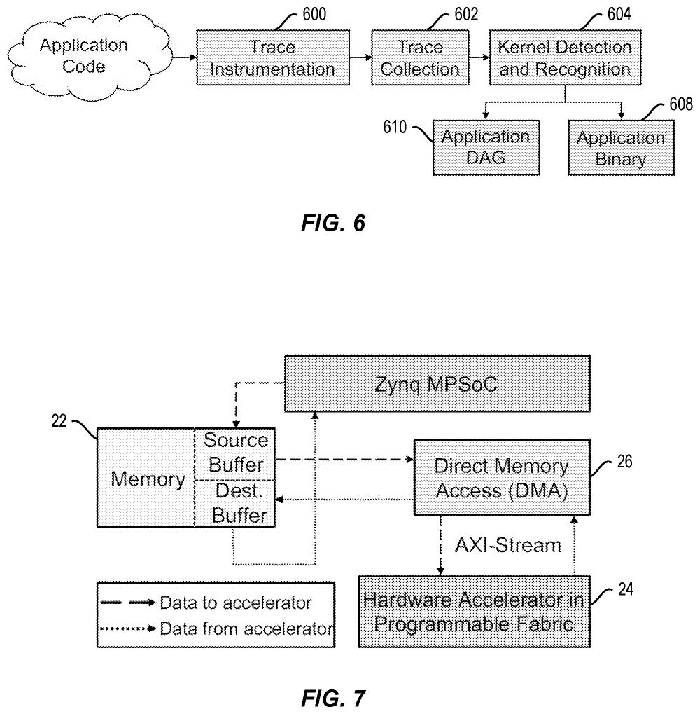

FIG. 6 is a block schematic diagram of an exemplary dynamic tracing-based software flow used to automatically convert unlabeled C applications to DAG-based applications. In an exemplary aspect, the Clang compiler is used to convert the application into a language-independent intermediate representation (IR) (e.g., LLVM) and a rich set of tools are applied from the open source LLVM ecosystem. Once an application is converted to LLVM IR, an open-source library called TraceAtlas is used, which enables instrumenting standard LLVM code with hooks for dynamic tracing-based analysis (block 600).

With the code instrumented, a tracing executable is compiled that dumps a runtime trace of its application behavior to disk (block 602). This trace is then analyzed through the TraceAtlas toolchain, and it identifies what sections of the code should be labeled as “kernels” or “non-kernels”, where a “kernel” is a set of highly correlated IR-level blocks from the original source code that execute frequently in the base program (block 604). In a broad sense, they are analogous to labeling “hot” sections in the source program. With this information, the original file can be partitioned into alternating groups of “cold”/“non-kernel” code and “hot”/“kernel” code.

This information is then passed through an in-house tool, built on LLVM's CodeExtractor module, that uses the information about these code groups to automatically refactor the LLVM IR into a sequence of function calls, where each function call invokes the proper group of blocks necessary to recreate the original application behavior. Additionally, this in-house tool analyzes the memory requirements of the original application by identifying both static memory allocation in terms of variable declarations as well as dynamic memory allocation by attempting to statically determine the parameters passed into initial malloc/calloc calls. With this information, along with the outlined source code via LLVM's CodeExtractor (block 606), embodiments are able to automatically generate a JSON-based DAG that is compatible with the runtime framework presented here (block 608).

Thanks to the flexibility present in having each node abstracted as a function call, this JSON-based DAG can actually improve an application's execution by replacing a particular node's run_func with an optimized invocation that has the same function signature if a particular kernel is able to be recognized. For example, recognizing a naive for loop-based discrete Fourier transform (DFT) would allow this compilation process to substitute in a call to an FFT library or add support for an FFT accelerator. By compiling the modified IR source into a shared object, it can be used along with the JSON-based DAG to functionally recreate the user-provided application in the runtime framework. The end result is unlikely to be as optimized and parallelized at this stage as a hand-crafted DAG, but it provides a quick path for porting functionally correct code into the runtime presented.

### III. Case Studies

This section presents four case studies to demonstrate the usability and portability of the proposed emulation framework 10 (e.g., emulation environment). In the first study, the validation mode of the framework is used to identify a suitable heterogeneous SoC configuration to meet the performance requirements. In the second study, the performance mode is used to narrow down on the scheduling policy for a given application domain. The portability of the framework is demonstrated by conducting a similar study on a different COTS platform in the third case study. As a fourth case study, the compilation toolchain that maps unlabeled, monolithic code to a DSSoC is illustrated. This section begins by providing a brief description of the hardware platforms and signal processing applications used for the studies.

A. Hardware Platforms and Applications

ZCU102 and Odroid XU3 platforms are used in the case studies. ZCU102 is a general-purpose evaluation kit built on top of Zynq UltraScale+™ MPSoC. This MPSoC combines general-purpose processing units (quad-core ARM Cortex A53 and dual-core Cortex-R5) and programmable fabric on a single chip. A resource pool is created which is composed of two FFT accelerators on the programmable fabric and three general-purpose CPU A53 cores to instantiate different heterogeneous SoC configurations. The fourth A53 core is used as an overlay processor to run the workload manager 14 and the application handler 12. On this platform, direct memory access (DMA) blocks are used to facilitate the transfer of data between memory and hardware accelerators through AXI4-Stream, a streaming protocol.

FIG. 7 is a schematic block diagram illustrating data transfer mechanisms among the host software application, memory 22, and accelerators 24. This example uses udmabuf, an open-source Linux driver that allocates contiguous memory blocks in the kernel space and makes it user-accessible. A software application, which operates in the user-space, writes into the shared memory 22 space to transfer data to the programmable logic. The DMA IP 26 moves the data to the accelerator 24 for processing and transfers the computed output to the shared memory 22. The software application then reads the data coordinated with the appropriate control logic from DMA 26 and the accelerator 24.

Odroid XU3 is a single board computer, which features an Exynos 5422 SoC. The SoC is based on the ARM heterogeneous big.LITTLE architecture in which the LITTLE cores are highly energy-efficient (Cortex-A7) and the big cores (Cortex-A15) are performance-oriented. The Cortex-A7 and Cortex-A15 in this SoC are quad-core 32-bit multi-processor cores implementing the ARMv7-A architecture. One of the LITTLE cores is used as an overlay processor to run the workload manager 14 and the application handler 12. The remaining four BIG cores and three LITTLE cores form the resource pool to instantiate different heterogeneous SoC configurations.

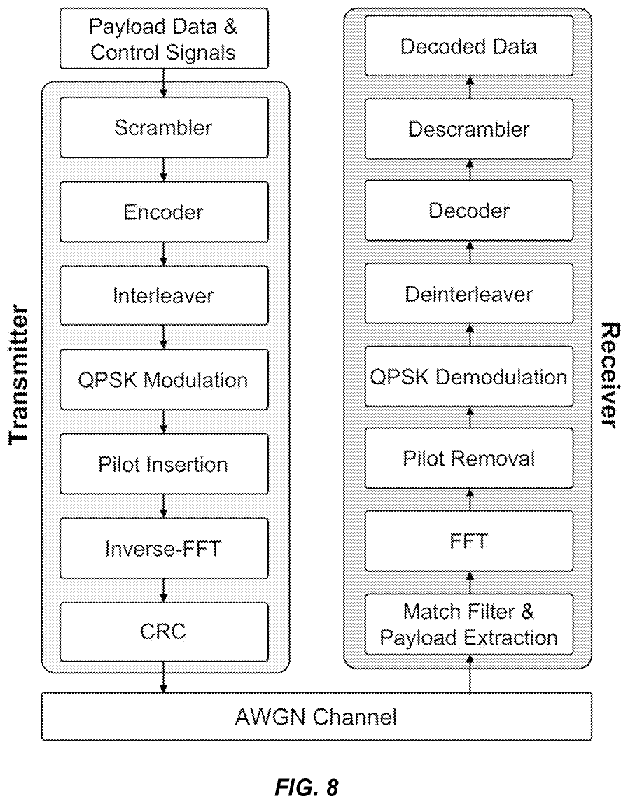

FIG. 8 is a block schematic diagram of WiFi transmitter and receiver applications used to evaluate embodiments of the emulation framework 10. WiFi (RX/TX), Pulse Doppler, and range detection are selected as a representative set of applications in the domain of software-defined radio (SDR). The WiFi transmitter and receiver applications process 64 bits of data in one frame and are segmented into the kernels shown in FIG. 8. It is composed of various compute-intensive blocks, such as FFT, modulation, demodulation, Viterbi decoder, and scrambler.

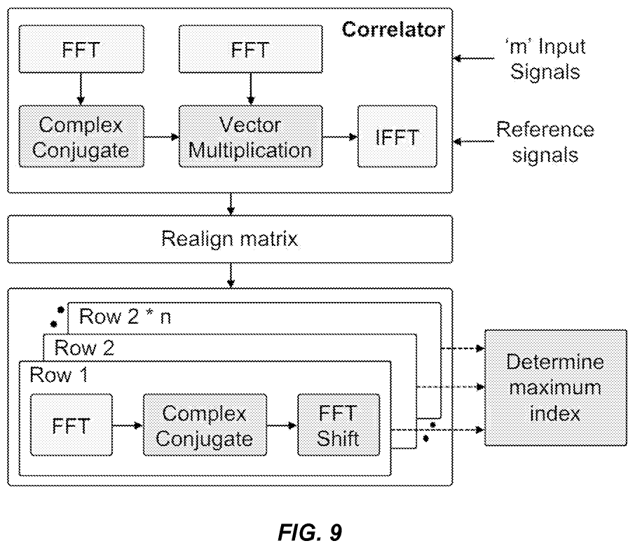

FIG. 9 is a block schematic diagram of an exemplary Pulse Doppler application used to evaluate embodiments of the emulation framework 10. Range detection and Pulse Doppler applications are used in radar to determine the distance and velocity, respectively, of the target object from the reference signal source. FIGS. 2 and 9 present the kernel compositions for the range detection and the Pulse Doppler, respectively. The DAG representations for these four applications are handcrafted for the case studies on validation and performance modes.

B. Case Study 1: Validation Mode

The primary use of the validation mode is to functionally verify the integration of an application task-graph, scheduling algorithm, and accelerator in the emulation framework 10. The validation mode is also used to obtain an estimate on the workload execution time and PE 18 utilization on different SoC configurations. The estimates obtained on the emulation framework 10 are not designed to be cycle-accurate compared to the real silicon chip. Instead, it is designed to assist hardware and software designers to obtain relative performance and PE 18 utilization of a given workload on different target SoC configurations.

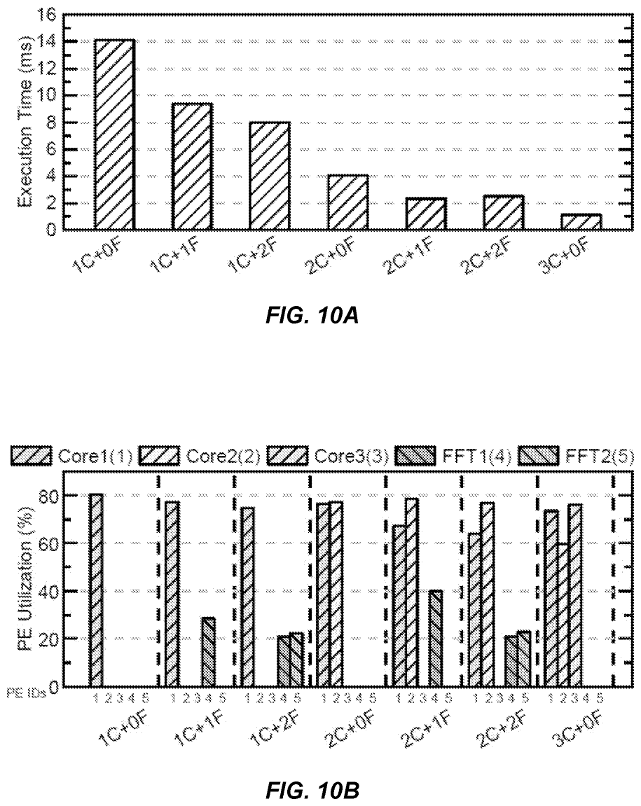

FIG. 10A is a graphical representation of execution time across various heterogeneous SoC configurations for a workload composed of single instances of Pulse-Doppler, range detection, and WiFi applications. FIG. 10B is a graphical representation of average PE utilization across various heterogeneous SoC configurations for a workload composed of single instances of Pulse-Doppler, range detection, and WiFi applications. FIG. 10A is generated based on the execution time for 50 iterations of running this workload. The ZCU102 platform is used for this study and the ready tasks are dynamically scheduled in the given workload based on the FRFS scheduling policy. In FIGS. 10A and 10B an improvement in the workload execution time is observed with the increase in PE count.

However, the increase in CPU cores results in a greater improvement in the execution time compared to the FFT accelerators, i.e., execution time improvement is higher as the study moves from 1Core+1FFT to 2Core+1 FFT configuration compared to 1Core+2FFT configuration. This behavior is observed because the input sample count to the FFT accelerator is only 128. On the ZCU102 platform, an FFT of this size has a faster turn-around time on a CPU core compared to the FFT accelerator. The overhead associated with the data transfer from the main memory to programmable fabric and vice-versa in the ZCU102 platform limits the usability of the programmable fabric in processing such a small data set.

A negligible difference is observed between the execution times on 2Core+1 FFT and 2Core+2FFT configurations. This is because, for the 2Core+2FFT configuration, the resource manager 16 threads for the FFT accelerators share the CPU core. As a result, they keep cyclically preempting each other. The overhead involved in the OS level thread preemption and thread scheduling ends up dominating the benefits of using two FFT accelerators in this configuration. For the remaining configurations in the figures, each resource manager 16 thread executes on a dedicated CPU core. This ensures the improvement in the execution time with the increase in the PEs 18 in the heterogeneous SoC configuration.

PE resource utilization is calculated by computing the ratio between the usage time of a PE 18 and the total execution time of the workload. The utilization of the CPU cores is significantly higher than the FFT accelerators for the heterogeneous SoC. The maximum CPU core utilization observed is 80% for the 1Core+0FFT configuration. Because embodiments regularly execute the scheduling algorithm on the completion of each task, significant scheduling overhead is incurred. However, some embodiments incorporate task reservation queues on each PE 18 to reduce the impact of the scheduling overhead. From FIGS. 10A and 10B the 3Core+0FFT configuration has the best execution time. If the area and performance are the primary concerns, though, then the 2Core+1 FFT configuration is more area efficient while delivering a comparable performance compared to that of the 3Core+0FFT configuration for the given workload.

C. Case Study 2: Performance Mode

This case study compares the performance of different scheduling algorithms (FRFS, MET, and EFT) on a DSSoC configuration composed of three cores and two FFT accelerators. The emulation framework 10 is operated in the performance mode. This mode is designed to emulate the dynamic injection of the applications on a target heterogeneous SoC. In the performance mode, the user needs to provide the frequency and probability of injection for each application. The user also needs to input the timeframe during which applications are injected. For the evaluation, it is assumed that applications are injected periodically with the probability of one in the test timeframe of 100 milliseconds. To create a new workload trace, the periodic duration is varied for each application to alter the average injection rate. Table I presents the standalone execution time for each application on a 3Core+2FFT SoC configuration. Table II presents the instance count for a given application in each workload trace. Compared to Pulse Doppler, higher injection frequencies are chosen for the range detection and WiFi applications because of their shorter execution time and smaller DAG.

TABLE I
Application execution time and task count on three core
and two FFT accelerators using FRFS scheduling policy

| Application | Execution Time (ms) | Task Count |
|---|---|---|
| Range Detection | 0.32 | 6 |
| Pulse Doppler | 5.60 | 770 |
| WiFi TX | 0.13 | 7 |
| WIFI RX | 2.22 | 9 |

TABLE II
Application instance count used for different injection
rates in case study 2

| Infection Rate | Pulse | Range | WiFi | WiFi |
|---|---|---|---|---|
| (jobs per msec) | Doppler | Detection | TX | RX |
| 1.71 | 8 | 123 | 20 | 20 |
| 2.28 | 10 | 164 | 27 | 27 |
| 3.42 | 15 | 245 | 41 | 41 |
| 4.57 | 18 | 329 | 55 | 55 |
| 6.92 | 32 | 495 | 82 | 83 |

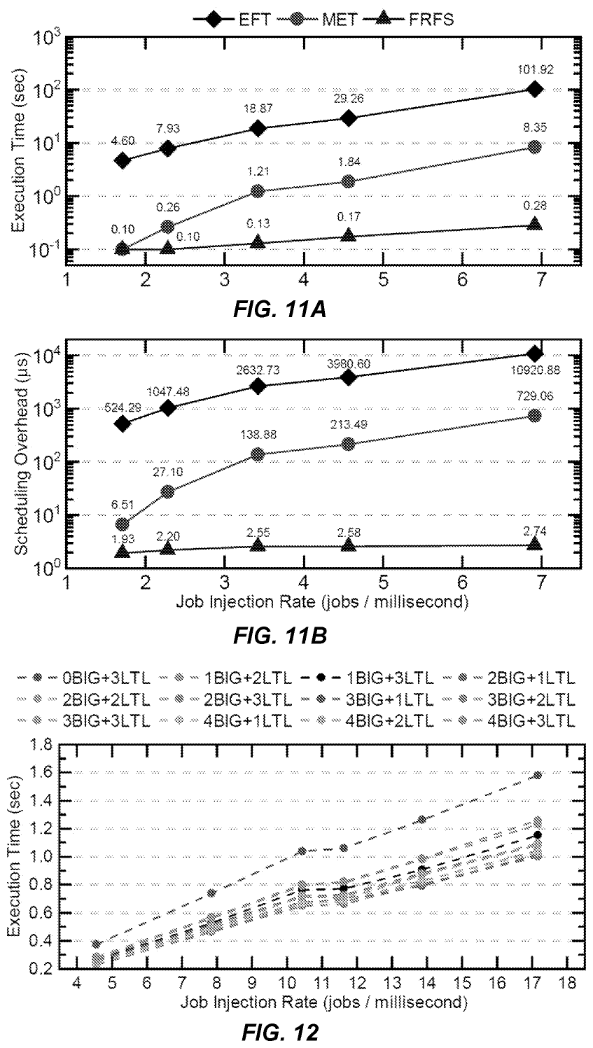

FIG. 11A is a graphical representation of workload execution time for different scheduling policies on a 3Core+2FFT configuration. FIG. 11B is a graphical representation of average scheduling overhead for different scheduling policies on a 3Core+2FFT configuration. This example calculates scheduling overhead by accumulating the time required to monitor the completion status of the running tasks, updates ready queue, runs scheduling algorithm on ready tasks, and communicates ready tasks to resource managers 16 for execution.

In FIGS. 11A and 11B, the sophisticated scheduling policies, such as EFT and MET, under-perform in terms of workload execution time compared to a simple scheduling policy of FRFS. This is because the computation complexity associated with these schedulers adds up to a significant scheduling overhead as opposed to FRFS policy. The computation complexities for the MET and EFT algorithms are O(n) and O(n²), respectively. Due to the unavailability of the reservation queue on each PE 18, a scheduling algorithm incurs this overhead every time a task completes its execution on the PE 18. Eventually, these overheads start accumulating into the workload execution time. In the proposed framework, the complexity of FRFS is equal to the number of PEs 18 in the emulated SoC for the selected group of applications. As a result, a constant scheduling overhead of 2.5 microseconds and a linear increase in the execution time are observed with the increase in the application injection rate for the selected set of applications.

The framework is successfully able to expose the limitations of underlying design decisions related to the SoC configuration and scheduling policies for a given set of applications. Traditionally, researchers use discrete event-based simulation tools, such as DS3 and SimGrid, to develop and evaluate new scheduling algorithms. These simulators rely on statistical profiling information to realize the performance of general-purpose cores and hardware accelerators. As a result, they are inadequate in capturing scheduling overhead and performing functional validation of the system and IP, as they are designed to operate without real applications and hardware. Cycle-accurate simulators, such as gem5 and PTLSim, address the drawbacks of discrete event simulators by performing cycle-by-cycle execution of the real applications and scheduling algorithms for the simulated target system or IP. However, these simulators are slow and primarily used to validate individual IP designs or few specific testcases for full system validation. The turnaround time of the emulation framework 10 is substantially lower compared to the cycle-accurate simulators, and its capability to capture the impact of scheduling overheads on the total execution time provide better estimates while performing design space exploration compared to the discrete event simulators.

D. Case Study 3: Performance Analysis on Odroid XU3

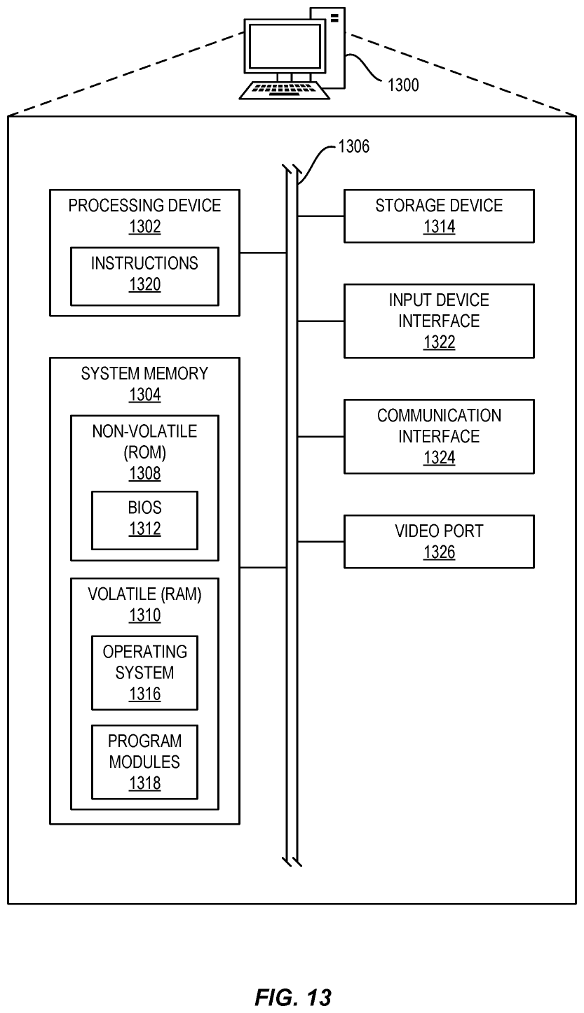

FIG. 12 is a graphical representation of an execution time trend with respect to change in job injection rate for different combinations of BIG and LITTLE cores on Odroid XU3. In this case study, an embodiment of the framework is executed in the performance mode on Odroid XU3 to demonstrate its portability across different COTS platforms. An approach similar to the one described in case study 2 is used to create a test workload. For a given injection rate, the same workload is used across all the configurations. Each evaluation is repeated for multiple iterations and the average execution time is computed to plot points in FIG. 12.

A linear correlation between the workload execution time and the job injection rate is observed. The configuration composed of three BIG cores and two LITTLE cores, i.e., 3BIG+2LTL, has the best execution time across different job injection rates. The configurations 3BIG+1 LTL, 4BIG+1 LTL, and 2BIG+3LTL perform comparable to the best performing configuration with less than 3% of impact on the performance. Interestingly, the workload execution time on the configurations 4BIG+3LTL and 4BIG+2LTL is higher than the execution time on the configuration 4BIG+1 LTL. This is because, in the framework, the scheduling complexity of the FRFS algorithm is proportional to the number of PEs 18 in the emulated SoC. As the PE count in the emulated SoC increases, the scheduling overhead becomes noticeable compared to the task execution time. Furthermore, the lower operating frequency of the overlay processor (LITTLE core) increases the scheduling overhead.

E. Case Study 4: Automatic Application Conversion

The preceding case studies have primarily focused on exploring performance estimates for different heterogeneous SoC configurations and workload scenarios while holding the applications used for evaluation fixed. However, demonstrating a meaningful path by which application developers can map novel applications to a fixed heterogeneous SoC configuration is a similarly critical part of the overall heterogeneous SoC design process. In this case study, the capabilities of the dynamic tracing-based compilation toolchain are explored through automatic mapping of a monolithic range detection C code to the emulation environment. The ZCU102 platform is targeted with a configuration composed of 3 cores and 1 FFT accelerator.

As described in Section II-D, the toolchain works by using TraceAtlas to dynamically trace the baseline application and extract kernels of interest via analysis of this runtime trace. In range detection, among the six kernels that are currently detected, three of them consist of heavy file I/O, along with two kernels consisting of two FFTs and one kernel consisting of the IFFT as shown previously in FIG. 2. With the kernels identified in this application, they are labeled as such in the original application LLVM, and the remaining contiguous blocks of code are labeled as non-kernels. The in-house tool is then used to refactor each contiguous group of kernel/non-kernel LLVM IR into standalone functions and transform the original application into a sequence of function calls, where each outlined function represents one of the nodes in the automatically created DAG. Together with analysis of the variable and memory requirements for this application, a JSON-based DAG is generated that is able to invoke the outlined functions in an order that preserves the program's correctness.

For this particular application, the two FFTs and one IFFT were implemented as simple for-loop based DFTs and an inverse DFT (IDFT). As such, to explore the inherent ability to optimize through selecting semantically equivalent but highly optimized run_func invocations, an additional shared object library is compiled that contains two optimized implementations of the DFT kernel: one that uses FFTW compiled for ARM to invoke a highly optimized FFT and one that targets the FFT accelerator present on the ZCU102's programmable logic to test the framework's ability to transparently add support for accelerators. Through hash-based kernel recognition, the platform entries in the DAG JSON were then automatically redirected to this shared object through use of the shared object key as first demonstrated in the FFT_0 node of FIG. 3. When replacing this naive DFT kernel with an FFTW call on ARM, including overheads related to FFTW setup and memory allocation, a 102× average speedup is observed across both DFT kernel executions, and the application output remains correct. Similarly, when replacing the DFT kernel with an FPGA-based accelerator call, including data transfer overhead, a 94× average speedup is observed across both DFT executions, and the output remains correct.

While these results do require a fairly strict assumption that it is possible to recognize a kernel operationally in an automatic compilation process with no human input, these results present a promising pathway forward in exploring a generalizable compilation flow for heterogeneous SoCs. Despite this being a first pass implementation of such a compilation flow, benefits are observed through new optimization opportunities on the CPU side and through the ability to add automatic support for heterogeneous accelerators without any user intervention or compiler directives. Some embodiments enable further benefits such as support for automatic parallelization of independent kernels via analysis of their runtime memory access patterns and a more generalizable approach for recognizing kernels and pairing them with compatible optimized invocations.

### IV. Computer System

FIG. 13 is a block diagram of a computer system 1300 suitable for implementing an emulation framework 10 for heterogeneous SoC design according to embodiments disclosed herein. Embodiments described herein can include or be implemented as the computer system 1300, which comprises any computing or electronic device capable of including firmware, hardware, and/or executing software instructions that could be used to perform any of the methods or functions described above. In this regard, the computer system 1300 may be a circuit or circuits included in an electronic board card, such as a printed circuit board (PCB), a server, a personal computer, a desktop computer, a laptop computer, an array of computers, a personal digital assistant (PDA), a computing pad, a mobile device, or any other device, and may represent, for example, a server or a user's computer.

The exemplary computer system 1300 in this embodiment includes a processing device 1302 or processor, a system memory 1304, and a system bus 1306. The system memory 1304 may include non-volatile memory 1308 and volatile memory 1310. The non-volatile memory 1308 may include read-only memory (ROM), erasable programmable read-only memory (EPROM), electrically erasable programmable read-only memory (EEPROM), and the like. The volatile memory 1310 generally includes random-access memory (RAM) (e.g., dynamic random-access memory (DRAM), such as synchronous DRAM (SDRAM)). A basic input/output system (BIOS) 1312 may be stored in the non-volatile memory 1308 and can include the basic routines that help to transfer information between elements within the computer system 1300.

The system bus 1306 provides an interface for system components including, but not limited to, the system memory 1304 and the processing device 1302. The system bus 1306 may be any of several types of bus structures that may further interconnect to a memory bus (with or without a memory controller), a peripheral bus, and/or a local bus using any of a variety of commercially available bus architectures.

The processing device 1302 represents one or more commercially available or proprietary general-purpose processing devices, such as a microprocessor, CPU, or the like. More particularly, the processing device 1302 may be a complex instruction set computing (CISC) microprocessor, a reduced instruction set computing (RISC) microprocessor, a very long instruction word (VLIW) microprocessor, a processor implementing other instruction sets, or other processors implementing a combination of instruction sets. The processing device 1302 is configured to execute processing logic instructions for performing the operations and steps discussed herein.

In this regard, the various illustrative logical blocks, modules, and circuits described in connection with the embodiments disclosed herein may be implemented or performed with the processing device 1302, which may be a microprocessor, field programmable gate array (FPGA), a digital signal processor (DSP), an application-specific integrated circuit (ASIC), or other programmable logic device, a discrete gate or transistor logic, discrete hardware components, or any combination thereof designed to perform the functions described herein. Furthermore, the processing device 1302 may be a microprocessor, or may be any conventional processor, controller, microcontroller, or state machine. The processing device 1302 may also be implemented as a combination of computing devices (e.g., a combination of a DSP and a microprocessor, a plurality of microprocessors, one or more microprocessors in conjunction with a DSP core, or any other such configuration).

The computer system 1300 may further include or be coupled to a non-transitory computer-readable storage medium, such as a storage device 1314, which may represent an internal or external hard disk drive (HDD), flash memory, or the like. The storage device 1314 and other drives associated with computer-readable media and computer-usable media may provide non-volatile storage of data, data structures, computer-executable instructions, and the like. Although the description of computer-readable media above refers to an HDD, it should be appreciated that other types of media that are readable by a computer, such as optical disks, magnetic cassettes, flash memory cards, cartridges, and the like, may also be used in the operating environment, and, further, that any such media may contain computer-executable instructions for performing novel methods of the disclosed embodiments.

An operating system 1316 and any number of program modules 1318 or other applications can be stored in the volatile memory 1310, wherein the program modules 1318 represent a wide array of computer-executable instructions corresponding to programs, applications, functions, and the like that may implement the functionality described herein in whole or in part, such as through instructions 1320 on the processing device 1302. The program modules 1318 may also reside on the storage mechanism provided by the storage device 1314. As such, all or a portion of the functionality described herein may be implemented as a computer program product stored on a transitory or non-transitory computer-usable or computer-readable storage medium, such as the storage device 1314, volatile memory 1310, non-volatile memory 1308, instructions 1320, and the like. The computer program product includes complex programming instructions, such as complex computer-readable program code, to cause the processing device 1302 to carry out the steps necessary to implement the functions described herein.

An operator, such as the user, may also be able to enter one or more configuration commands to the computer system 1300 through a keyboard, a pointing device such as a mouse, or a touch-sensitive surface, such as the display device, via an input device interface 1322 or remotely through a web interface, terminal program, or the like via a communication interface 1324. The communication interface 1324 may be wired or wireless and facilitate communications with any number of devices via a communications network in a direct or indirect fashion. An output device, such as a display device, can be coupled to the system bus 1306 and driven by a video port 1326. Additional inputs and outputs to the computer system 1300 may be provided through the system bus 1306 as appropriate to implement embodiments described herein.

The operational steps described in any of the exemplary embodiments herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary embodiments may be combined.

Those skilled in the art will recognize improvements and modifications to the preferred embodiments of the present disclosure. All such improvements and modifications are considered within the scope of the concepts disclosed herein and the claims that follow.

What is claimed is:

1. An emulation environment for heterogeneous system-on-chip (SoC) design, comprising:
a workload manager configured to schedule application tasks onto heterogeneous processing elements (PEs) in a heterogeneous SoC based on a scheduling policy; and
a resource manager configured to simulate a test hardware configuration using the heterogeneous PEs and execute the application tasks scheduled by the workload manager.

2. The emulation environment of claim 1, wherein the application tasks comprise heterogeneous application tasks.

3. The emulation application of claim 1, further comprising an application handler configured to generate a workload comprising the application tasks.

4. The emulation environment of claim 2, wherein the application handler is further configured to generate workloads for different applications from hardware-agnostic application code.

5. The emulation environment of claim 2, wherein the application handler is further configured to receive an application code in form of:
a directed acyclic graph (DAG) for the application tasks; and
a binary compilation of the application.

6. The emulation environment of claim 5, workload manager is further configured to receive the DAG from the application handler and manage dependencies between the application tasks.

7. The emulation environment of claim 1, wherein the workload manager comprises:
an application tracker configured to track application tasks for each of a plurality of applications;
a resource tracker configured to track availability of the heterogeneous PEs; and
a modular scheduler configured to provide the scheduling policy.

8. The emulation environment of claim 7, wherein the modular scheduler is further configured to map the application tasks to corresponding PEs based on the availability of the heterogeneous PEs.

9. The emulation environment of claim 1, wherein the resource manager is further configured to dispatch to hardware resources via application threads.

10. The emulation environment of claim 9, wherein the resource manager is further configured to coordinate data flow between the hardware resources during simulation.

11. The emulation environment of claim 1, wherein the heterogeneous PEs of the heterogeneous SoC comprises one or more general processor clusters and one or more hardware accelerator clusters.

12. The emulation environment of claim 11, wherein the one or more hardware accelerator clusters comprises at least one of: a cluster of matrix multipliers, a cluster of Viterbi decoders, a cluster of fast Fourier transform (FFT) accelerators, a cluster of graphical processing units (GPUs), a cluster of digital signal processors (DSPs), or a cluster of tensor processing units (TPUs).

13. A method for developing an application for heterogeneous system-on-chip (SoC) implementation, the method comprising:
obtaining an application code;
converting the application code into a platform-independent hardware representation; and
generating an object notation-based representation of the application code for heterogeneous SoC implementation from the platform-independent hardware representation.

14. The method of claim 13, wherein the application code is for an application comprising a plurality of heterogeneous application tasks.

15. The method of claim 13, further comprising:
generating a directed acyclic graph (DAG) for the plurality of heterogeneous application tasks; and
using the DAG to manage dependencies between the plurality of heterogeneous application tasks for the heterogeneous SoC implementation.

16. The method of claim 13, further comprising scheduling execution of the object notation-based representation of the application code onto heterogeneous processing elements (PEs) in the heterogeneous SoC.

17. The method of claim 16, further comprising emulating a hardware configuration of the heterogeneous SoC and executing the object notation-based representation of the application code therein.

18. The method of claim 17, further comprising generating workloads for emulating a plurality of different applications using the hardware configuration of the heterogeneous SoC.

19. The method of claim 16, wherein scheduling execution of the object notation-based representation of the application code further comprises:
tracking application tasks for the application code; and
tracking availability of the heterogeneous PEs.

20. The method of claim 19, further comprising mapping the application tasks to corresponding PEs based on the availability of the heterogeneous PEs.
